(19) United States
(12) Patent Application Publication
(10) Pub. No.: US 2020/0234999 A1
(43) Pub. Date: Jul. 23, 2020

(54) GAPS IN TRANSISTOR GATE METAL

(71) Applicant: QUALCOMM Incorporated, San Diego, CA (US)

(72) Inventors: Ye LU, San Diego, CA (US); Junjing BAO, San Diego, CA (US); Peijie FENG, San Diego, CA (US); Chenjie TANG, San Diego, CA (US)

(21) Appl. No.: 16/250,098

(22) Filed: Jan. 17, 2019

(51) Int. Cl. H01L 21/764; H01L 27/092; H01L 21/8238

(52) U.S. Cl. CPC H01L 21/764; H01L 21/823878; H01L 21/823821; H01L 27/0924

(57) ABSTRACT

Certain aspects of the present disclosure provide a transistor device, such as a fin field-effect transistor (finFET) device, and techniques for fabrication thereof. One example transistor device generally includes one or more semiconductor channel regions and a metal region disposed above the one or more semiconductor channel regions. The metal region has one or more gaps (e.g., air gaps) disposed therein.

### TECHNICAL FIELD

Certain aspects of the present disclosure generally relate to electronic circuits and, more particularly, to transistors having a gate metal region with gaps formed therein.

### BACKGROUND

Complementary metal-oxide semiconductor (CMOS) devices are fundamental components for integrated circuits to implement digital logic. A CMOS device typically includes a p-type metal-oxide semiconductor (PMOS) used to pull an output to logic high and an n-type metal-oxide semiconductor (NMOS) used to pull the output down to logic low, depending on an input signal provided to the gates of the PMOS and NMOS transistors. Advanced CMOS technology may be implemented with fin field-effect transistors (finFETs), for example, to provide significantly faster switching speeds and higher current density.

### SUMMARY

Certain aspects of the present disclosure generally relate to transistors having gaps in a gate metal region.

Certain aspects of the present disclosure are directed to a transistor device. The transistor device generally includes one or more semiconductor channel regions and a metal region disposed above the one or more semiconductor channel regions, the metal region comprising one or more gaps.

Certain aspects of the present disclosure are directed to an integrated circuit (IC). The IC generally includes a complementary metal-oxide semiconductor (CMOS) logic gate implemented with a transistor device. The transistor device generally includes one or more semiconductor channel regions and a metal region disposed above the one or more semiconductor channel regions, the metal region comprising one or more gaps.

Certain aspects of the present disclosure are directed to a method for fabricating a transistor device. The method generally includes forming a plurality of semiconductor channel regions and forming a metal region disposed above the plurality of semiconductor channel regions. The metal region includes a plurality of gaps.

### BRIEF DESCRIPTION OF THE DRAWINGS

So that the manner in which the above-recited features of the present disclosure can be understood in detail, a more particular description, briefly summarized above, may be by reference to aspects, some of which are illustrated in the appended drawings. It is to be noted, however, that the appended drawings illustrate only certain typical aspects of this disclosure and are therefore not to be considered limiting of its scope, for the description may admit to other equally effective aspects.

FIG. 1A is a conceptual top view of an example fin field-effect transistor (finFET) device, illustrating parasitic capacitance between the gate metal and the source and drain contact electrodes.

FIG. 1B is a conceptual cross-sectional view of the finFET device of FIG. 1A along the line AA′, illustrating a solid gate metal region surrounding the semiconductor fins.

FIG. 1C is an alternative conceptual cross-sectional view of the finFET device of FIG. 1A along the line AA′, illustrating gaps in the gate metal region, in accordance with certain aspects of the present disclosure.

FIG. 2 is a computer-aided design (CAD) simulation of a complementary metal-oxide semiconductor (CMOS) device having gaps in the gate metal regions, in accordance with certain aspects of the present disclosure.

FIGS. 3A-3J conceptually illustrate an example process for fabricating a transistor device having gaps in the gate metal region, in accordance with certain aspects of the present disclosure.

FIG. 4 is a flow diagram of example operations for fabricating a transistor device, in accordance with certain aspects of the present disclosure.

### DETAILED DESCRIPTION

Certain aspects of the present disclosure are generally directed to semiconductor devices with transistors having gaps in a gate metal region.

The word “exemplary” is used herein to mean “serving as an example, instance, or illustration.” Any aspect described herein as “exemplary” is not necessarily to be construed as preferred or advantageous over other aspects.

As used herein, the term “connected with” in the various tenses of the verb “connect” may mean that element A is directly connected to element B or that other elements may be connected between elements A and B (i.e., that element A is indirectly connected with element B). In the case of electrical components, the term “connected with” may also be used herein to mean that a wire, trace, or other electrically conductive material is used to electrically connect elements A and B (and any components electrically connected therebetween).

### Example Semiconductor Devices

In certain advanced semiconductor technologies (e.g., 5 nm and smaller), the transistor gate metal couples to the source and/or drain contacts and creates parasitic capacitance. In advanced complementary metal-oxide semiconductor (CMOS) integrated circuits (ICs), for example, this parasitic capacitance significantly impacts the IC performance (e.g., degrades logic speed by more than 25%).

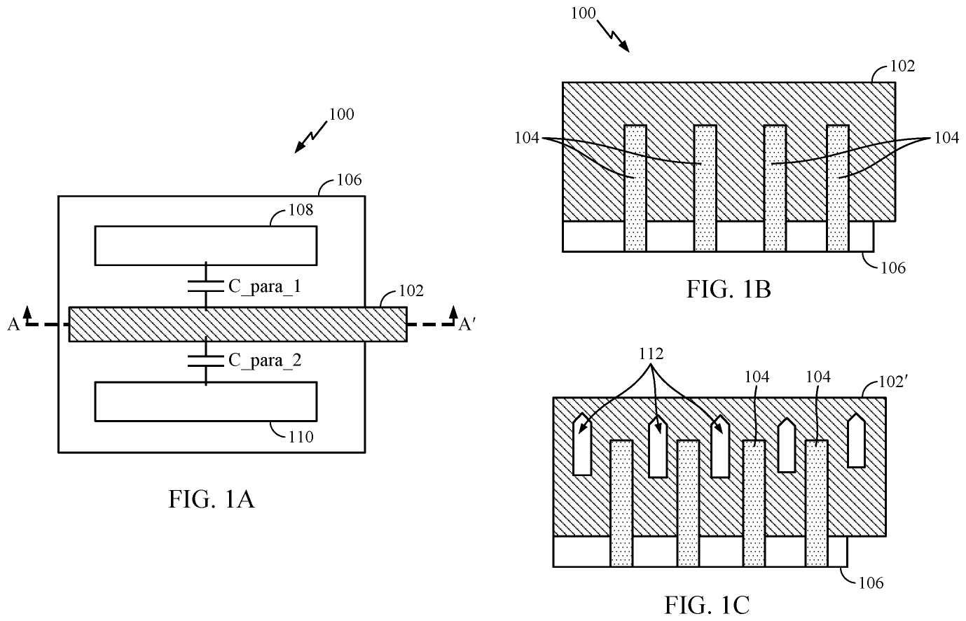

FIG. 1A is a conceptual top view of an example fin field-effect transistor (finFET) device 100, while FIG. 1B is a conceptual cross-sectional view of the finFET device 100 of FIG. 1A along the line AA′. In FIGS. 1A and 1B, the transistor gate metal region 102 wraps around the semiconductor fins 104, which may protrude from a substrate (not shown) through an isolation region 106 (e.g., a shallow trench isolation (STI) region) as illustrated. The gate metal region 102 couples to the contact electrode for the source region 108 and to the contact electrode for the drain region 110, creating parasitic capacitances C_para_1 and C_para_2, respectively.

As described above, these parasitic capacitances (e.g., C_para_1 and C_para_2) significantly affect the device performance. To explain, the dynamic energy of a semiconductor device may be computed as Cdyn=CV², where C is the total effective capacitance of all the device components and V is the voltage. A reasonable estimation of parasitic capacitance in a transistor is about 25% of C. Therefore, reducing the parasitic capacitance should substantially reduce energy consumption in advanced semiconductor technologies.

In FIG. 1B, the finFET device 100 has a solid gate metal region 102, which surrounds the semiconductor fins 104 and leads to more surface area for the gate metal region and, thus, relatively higher parasitic capacitance. Certain aspects of the present disclosure are generally directed to a transistor device having gaps (e.g., air gaps) in a gate metal region of the device. For example, FIG. 1C is an alternative conceptual cross-sectional view of the finFET device 100 of FIG. 1A along the line AA′, illustrating gaps 112 in the gate metal region 102′, in accordance with certain aspects of the present disclosure. These gaps 112 may be air gaps, for example, and thereby reduce the surface area of the gate metal region 102′ compared to the gate metal region 102 of FIG. 1B, thereby reducing the parasitic capacitances C_para_1 and C_para_2. For example, the gaps 112 may lead to a reduction in total effective capacitance C by 7%, therefore significantly improving device performance.

As illustrated in FIG. 1C, one of the gaps 112 is disposed between each adjacent pair of fins 104. For other aspects, more than one gap 112 may be disposed between an adjacent pair of fins 104. These multiple gaps may have the same or different dimensions and may be disposed at the same or different heights. For example, the multiple gaps may be stacked or staggered.

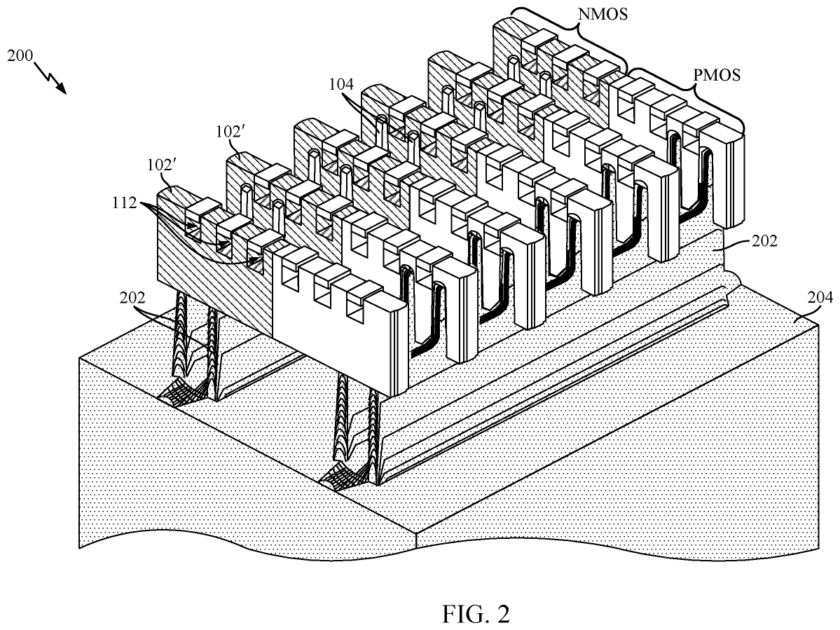

For certain aspects, the gaps 112 are each arranged with a longitudinal axis perpendicular to a longitudinal axis of the gate metal region 102′ (see also FIG. 2). Line segment AA′ in FIG. 1A may be considered as the longitudinal axis of the gate metal region 102′. For certain aspects, at least one of the gaps 112 may span a width of the gate metal region 102′ (i.e., the length of the gap 112 is equal to the width of the gate metal region 102′).

In FIG. 1C, the gate metal region 102′ is illustrated as completely surrounding lateral surfaces of the fins 104, in addition to the top surface, and extends from above the top surface of the fins down to the upper surface of the isolation region 106. For other aspects, the gate metal region 102′ may partially surround the lateral surfaces of the fins and may not extend down to the upper surface of the isolation region 106.

FIG. 2 is a computer-aided design (CAD) simulation of a complementary metal-oxide semiconductor (CMOS) device 200 having gaps 112 in the gate metal regions 102′, in accordance with certain aspects of the present disclosure. The CMOS device 200 includes a plurality of n-type metal-oxide semiconductor (NMOS) transistor devices and a plurality of p-type metal-oxide semiconductor (PMOS) transistor devices, as illustrated. The NMOS and PMOS devices are composed of finFET devices, where the semiconductor channel regions 202 of the finFET devices are formed (e.g., by epitaxial deposition) above a substrate 204 and include multiple fins 104. The source and drain regions 108, 110 have been removed in FIG. 2 to more clearly illustrate the linear arrangement of semiconductor channel regions 202 and the gate metal regions 102′ arranged perpendicular thereto and connecting an NMOS device to a PMOS device, as is understood to create CMOS logic gates (e.g., inverters).

As illustrated in FIG. 2, the gaps 112 may span a width of the gate metal regions 102′. For example, the gaps 112 may have a length (perpendicular to the longitudinal axis of the gate metal region) in a range of 10 to 15 nm, but may have a length that is greater or less than this range. The widths of the gaps 112 (parallel with the longitudinal axis of the gate metal region) may be about 5 nm, for example. The gaps 112 may also have a height in a range of 1 to 20 nm, for example. Because most of the conduction in the gate metal regions 102′ is above the fin portion, having gaps 112 should not adversely affect the gate conduction. Rather, the gaps 112 reduce the gate-metal-to-source/drain-contact parasitic coupling.

### Example Fabrication Operations

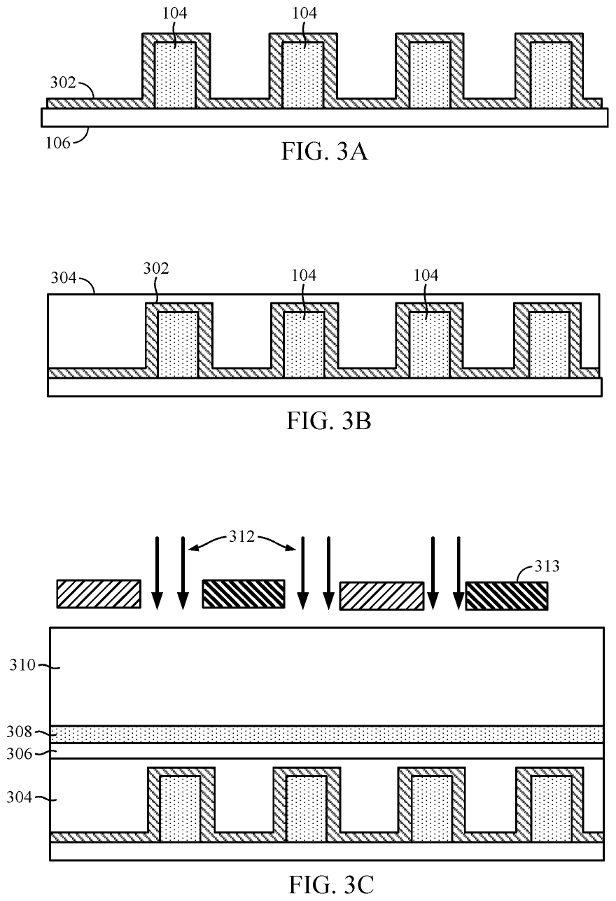

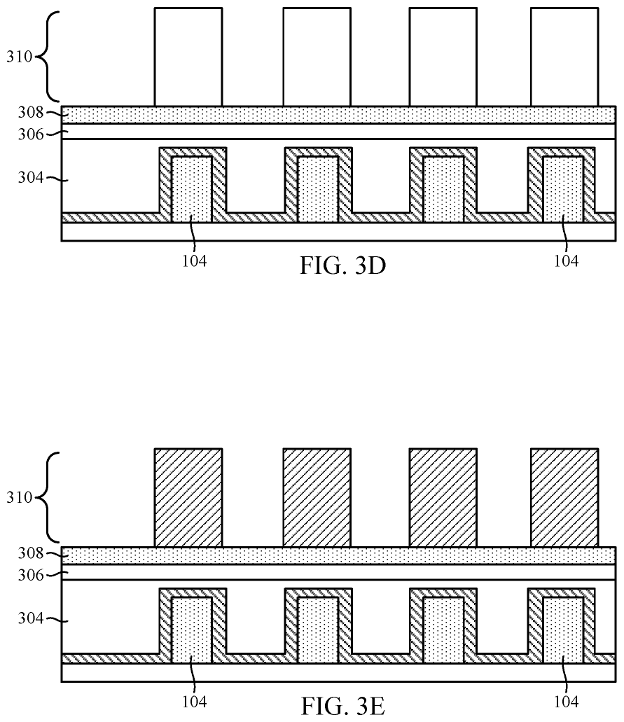

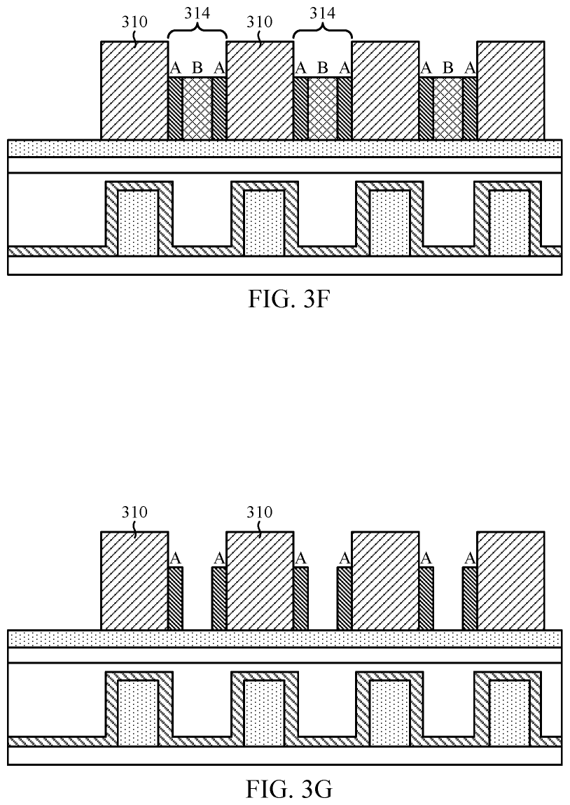

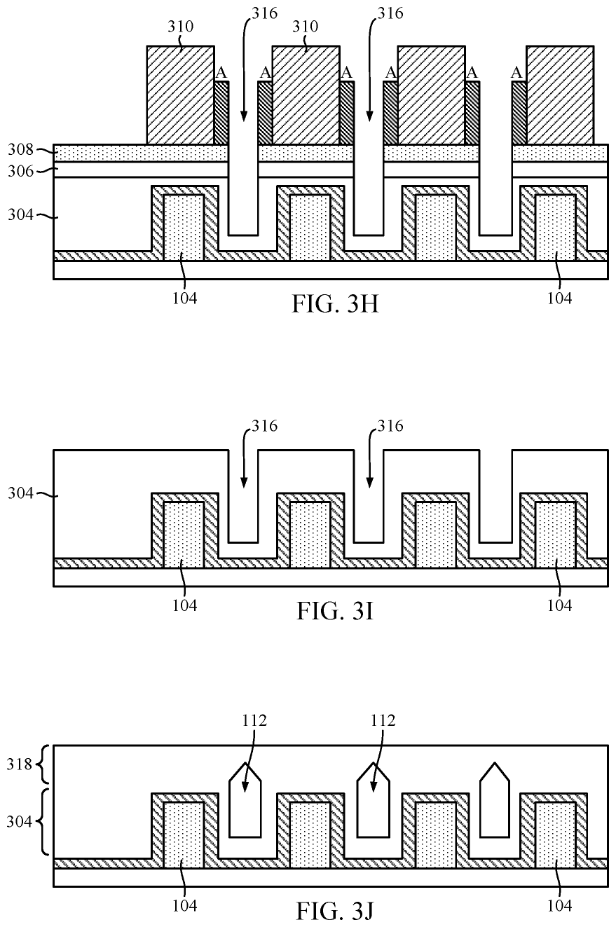

FIGS. 3A-3J conceptually illustrate an example process for fabricating a transistor device having gaps in the gate metal region, in accordance with certain aspects of the present disclosure. For example, the example process in FIGS. 3A-3J may be used to fabricate the finFET device 100 of FIGS. 1A and 1C or the CMOS device 200 of FIG. 2. The process may be performed by a semiconductor processing chamber, for example.

Starting with FIG. 3A, multiple fins 104 may be formed above an isolation region 106. The fins 104 may be covered with a high dielectric constant (high K) and work function metal layer 302. As illustrated in FIG. 3B, a metal layer 304 may be deposited (e.g., via electroplating) above the metal layer 302 and fill in spaces (e.g., trenches) between the fins 104. The metal layer 304 may comprise tungsten (W), for example, and may form a first portion of the metal region 102′ in the finished device. After the metal layer 304 is deposited, chemical-mechanical polishing (CMP) may be used, for certain aspects, to remove a portion of the metal layer 304.

As illustrated in FIG. 3C, a hard mask (HM) layer 306 and a neutral layer 308 may be deposited above the metal layer 304. Additionally or alternatively, an anti-reflective coating (ARC) layer (not shown) may be deposited above the metal layer 304. The chamber may deposit a resist layer 310 (e.g., a photoresist layer) above the HM layer 306, the neutral layer 308, and/or the ARC layer. The resist layer 310 may be subjected to multiple exposures 312 through a mask 313 to create directed self-assembly (DSA) guide patterns aligned with the underlying fins 104. The chamber then develops the resist layer 310, resulting in the structure illustrated in FIG. 3D where the remaining portions of the resist layer are aligned with the fins 104. Hardening of the developed resist layer 310 yields the structure illustrated in FIG. 3E.

As illustrated in FIG. 3F, the chamber applies (e.g., via coating) a copolymer layer 314 in the spaces (e.g., trenches) between the hardened remaining portions of the resist layer 310 (e.g., between adjacent pairs of resist elements) and anneals this copolymer layer. A copolymer comprises at least two different kinds of polymers (e.g., materials A and B), which are mixed when applied but separate after annealing. The annealed copolymer has good etch selectivity, where one type of polymer (e.g., material A) remains after etching, but another type of polymer (e.g., material B) is removed during etching, as illustrated in FIG. 3G after the copolymer layer 314 is etched (e.g., via low power oxygen reactive-ion etching (RIE)).

As illustrated in FIG. 3H, selective etching may be performed to remove portions of the HM layer 306, the neutral layer 308, and/or the ARC layer, as well as portions of the metal layer 304, according to the remaining polymer (e.g., material A). In this manner, a plurality of trenches 316 are formed between the hardened remaining portions of the resist layer 310 (e.g., between adjacent pairs of resist elements) and between the fins 104 (e.g., between adjacent pairs of semiconductor channel regions). The trenches may have a width of about 5 nm, for example.

As illustrated in FIG. 3I, the hardened resist layer 310 and the remaining portions of the copolymer layer 314 are removed. In addition, the chamber removes the HM layer 306, the neutral layer 308, and/or the ARC layer. As illustrated in FIG. 3J, the chamber may nonconformally grow (e.g., via electroplating) a metal layer 318 above the metal layer 304 to cover the trenches 316 and form the gaps 112. The metal layer 318 may comprise the same metal (e.g., W) as the metal layer 304. Considered as a lid to cap the trenches 316, the metal layer 318 may form a second portion of the metal region 102′ in the finished device.

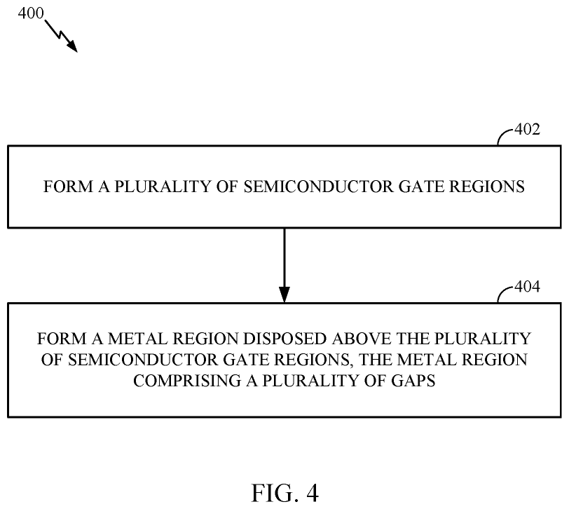

FIG. 4 is a flow diagram of example operations 400 for fabricating a transistor device, in accordance with certain aspects of the present disclosure. The operations 400 may be performed, for example, by a semiconductor processing chamber.

The operations 400 begin, at block 402, with the chamber forming a plurality of semiconductor channel regions (e.g., channel regions 202). At block 404, the chamber forms a metal region (e.g., gate metal region 102′) disposed above the plurality of semiconductor channel regions. The metal region comprises a plurality of gaps (e.g., gaps 112).

According to certain aspects, forming the metal region at block 404 involves a number of operations. For example, the chamber may form a first portion of the metal region above the plurality of semiconductor channel regions; form a resist layer above the first portion of the metal region, the resist layer having resist elements aligned above the semiconductor channel regions; dispose a copolymer layer between adjacent pairs of resist elements; anneal the copolymer layer; remove one type of polymer in the copolymer layer; form a plurality of trenches in the first portion of the metal region, each trench between adjacent pairs of resist elements and between adjacent pairs of semiconductor channel regions according to the removal; remove the resist layer and the copolymer layer; and deposit a second portion of the metal region above the first portion of the metal region such that the plurality of trenches are capped to form the plurality of gaps in the metal region. For certain aspects, the chamber may remove the one type of polymer in the copolymer layer by etching the copolymer layer, such that the one type of polymer in the copolymer layer is removed and another type of polymer in the copolymer layer remains.

According to certain aspects, the gaps are each arranged with a longitudinal axis perpendicular to a longitudinal axis (e.g., line segment AA′) of the metal region.

According to certain aspects, the transistor device is a fin field-effect transistor (finFET) device (e.g., finFET device 100). For certain aspects, the finFET device includes one or more fins (e.g., fins 104) arranged linearly, each fin including one of the semiconductor channel regions; a drain region (e.g., drain region 110) of the finFET device disposed on a first side of the one or more fins; and a source region (e.g., source region 108) of the finFET device disposed on a second side of the one or more fins. The second side may be opposite the first side. For certain aspects, the gaps in the metal region reduce a parasitic capacitance between the metal region and the drain and source regions of the finFET device by at least 50% compared to an equivalent finFET device having a metal region with no gaps therein (e.g., gate metal region 102 of FIG. 1B).

According to certain aspects, one of the gaps is disposed between each adjacent pair of channel regions.

According to certain aspects, at least one of the gaps spans a width of the metal region.

According to certain aspects, the metal region is disposed above the semiconductor channel regions and at least partially surrounds lateral surfaces of the semiconductor channel regions.

According to certain aspects, at least one of the gaps has a length in a range of 10 to 15 nm.

According to certain aspects, the gaps are occupied by air such that the gaps comprise air gaps.

In this manner, certain aspects of the present disclosure provide a graphoepitaxy method (a type of DSA technique) to introduce gaps inside the transistor gate metal, which may reduce gate-metal-to-S/D-contact parasitic capacitance by about 50%. CAD simulation has demonstrated that dynamic energy may be reduced by more than 7% due to the decreased parasitic capacitance relative to a gate metal region without gaps. No additional lithography operations are needed in the graphoepitaxy process, so not much cost is added. Furthermore, there is no impact to active parts of the transistor or other to devices in the circuit.

The various operations of methods described above may be performed by any suitable means capable of performing the corresponding functions. The means may include various hardware and/or software component(s) and/or module(s), including, but not limited to a circuit, an application-specific integrated circuit (ASIC), or processor. Generally, where there are operations illustrated in figures, those operations may have corresponding counterpart means-plus-function components with similar numbering.

As used herein, the term “determining” encompasses a wide variety of actions. For example, “determining” may include calculating, computing, processing, deriving, investigating, looking up (e.g., looking up in a table, a database, or another data structure), ascertaining, and the like. Also, “determining” may include receiving (e.g., receiving information), accessing (e.g., accessing data in a memory), and the like. Also, “determining” may include resolving, selecting, choosing, establishing, and the like.

As used herein, a phrase referring to “at least one of” a list of items refers to any combination of those items, including single members. As an example, “at least one of: a, b, or c” is intended to cover: a, b, c, a-b, a-c, b-c, and a-b-c, as well as any combination with multiples of the same element (e.g., a-a, a-a-a, a-a-b, a-a-c, a-b-b, a-c-c, b-b, b-b-b, b-b-c, c-c, and c-c-c or any other ordering of a, b, and c).

The methods disclosed herein comprise one or more steps or actions for achieving the described method. The method steps and/or actions may be interchanged with one another without departing from the scope of the claims. In other words, unless a specific order of steps or actions is specified, the order and/or use of specific steps and/or actions may be modified without departing from the scope of the claims.

It is to be understood that the claims are not limited to the precise configuration and components illustrated above. Various modifications, changes and variations may be made in the arrangement, operation and details of the methods and apparatus described above without departing from the scope of the claims.

1. A transistor device comprising:
one or more semiconductor channel regions; and
a metal region disposed above the one or more semiconductor channel regions, the metal region comprising one or more gaps.

2. The transistor device of claim 1, wherein the one or more gaps are each arranged with a longitudinal axis perpendicular to a longitudinal axis of the metal region.

3. The transistor device of claim 1, wherein the transistor device comprises a fin field-effect transistor (finFET) device.

4. The transistor device of claim 3, wherein the finFET device comprises:
one or more fins arranged linearly, each fin including one of the semiconductor channel regions;
a drain region of the finFET device disposed on a first side of the one or more fins; and
a source region of the finFET device disposed on a second side of the one or more fins, the second side being opposite the first side.

5. The transistor device of claim 4, wherein the one or more gaps in the metal region reduce a parasitic capacitance between the metal region and the drain and source regions of the finFET device by at least 50% compared to an equivalent finFET device having a metal region with no gaps therein.

6. The transistor device of claim 1, wherein the transistor device comprises a plurality of channel regions and wherein one of the gaps is disposed between each adjacent pair of channel regions.

7. The transistor device of claim 1, wherein at least one of the gaps spans a width of the metal region.

8. The transistor device of claim 1, wherein the metal region is disposed above the one or more semiconductor channel regions and at least partially surrounds lateral surfaces of the one or more semiconductor channel regions.

9. The transistor device of claim 1, wherein at least one of the gaps has a length in a range of 10 to 15 nm.

10. The transistor device of claim 1, wherein the one or more gaps are occupied by air such that the one or more gaps comprise one or more air gaps.

11. An integrated circuit (IC) comprising the transistor device of claim 1, wherein the IC comprises a complementary metal-oxide semiconductor (CMOS) logic gate implemented with the transistor device.

12. A method for fabricating a transistor device, the method comprising:
forming a plurality of semiconductor channel regions; and
forming a metal region disposed above the plurality of semiconductor channel regions, the metal region comprising a plurality of gaps.

13. The method of claim 12, wherein forming the metal region comprises:
forming a first portion of the metal region above the plurality of semiconductor channel regions;
forming a resist layer above the first portion of the metal region, the resist layer having resist elements aligned above the semiconductor channel regions;
disposing a copolymer layer between adjacent pairs of resist elements;
annealing the copolymer layer;
removing one type of polymer in the copolymer layer;
forming a plurality of trenches in the first portion of the metal region, each trench between adjacent pairs of resist elements and between adjacent pairs of semiconductor channel regions according to the removal;
removing the resist layer and the copolymer layer; and
depositing a second portion of the metal region above the first portion of the metal region such that the plurality of trenches are capped to form the plurality of gaps in the metal region.

14. The method of claim 13, wherein removing the one type of polymer in the copolymer layer comprises etching the copolymer layer such that the one type of polymer in the copolymer layer is removed and another type of polymer in the copolymer layer remains.

15. The method of claim 12, wherein each of the plurality of gaps is arranged with a longitudinal axis perpendicular to a longitudinal axis of the metal region.

16. The method of claim 12, wherein the transistor device comprises a fin field-effect transistor (finFET) device, wherein forming the plurality of semiconductor channel regions comprises forming a plurality of fins arranged linearly, and wherein each fin includes one of the semiconductor channel regions, the method further comprising:
forming a drain region of the finFET device on a first side of the plurality of fins; and
forming a source region of the finFET device on a second side of the plurality of fins, the second side being opposite the first side.

17. The method of claim 12, wherein one of the plurality of gaps is disposed between each adjacent pair of semiconductor channel regions.

18. The method of claim 12, wherein at least one of the plurality of gaps spans a width of the metal region.

19. The method of claim 12, wherein the metal region at least partially surrounds lateral surfaces of the plurality of semiconductor channel regions.

20. The method of claim 12, wherein at least one of the plurality of gaps has a length in a range of 10 to 15 nm.
